(19) United States
(12) Patent Application Publication
(10) Pub. No.: US 2009/0121266 A1
(43) Pub. Date: May 14, 2009

(54) METHODS AND STRUCTURES FOR EXCHANGE-COUPLED MAGNETIC MULTI-LAYER STRUCTURE WITH IMPROVED OPERATING TEMPERATURE BEHAVIOR

(75) Inventors: Srinivas V. Pietambaram, Chandler, AZ (US); Jason A. Janesky, Gilbert, AZ (US); Jon M. Slaughter, Tempe, AZ (US); Jijun Sun, Chandler, AZ (US)

Correspondence Address: INGRASSIA FISHER & LORENZ, P.C. (FS), 7010 E. COCHISE ROAD, SCOTTSDALE, AZ, 85253, US

(73) Assignee: FREESCALE SEMICONDUCTOR, INC., Austin, TX (US)

(21) Appl. No.: 11/938,816

(22) Filed: Nov. 13, 2007

(51) Int. Cl. H01L 27/108; H01L 21/02

(52) U.S. Cl. 257/295; 438/3; 257/E43.001; 257/E43.006

(57) ABSTRACT

Exchange-coupled magnetic multilayer structures for use with toggle MRAM devices and the like include a tunnel barrier layer (108) and a synthetic antiferromagnet (SAF) structure (300) formed on the tunnel barrier layer (108), wherein the SAF (300) includes a plurality (e.g., four or more) of ferromagnetic layers (302, 306, 310, 314) antiferromagnetically or ferromagnetically coupled by a plurality of respective coupling layers (304, 308, 312). The microcrystalline texture of one or more of the ferromagnetic layers is reduced to substantially zero as measured from X-Ray Diffraction by exposure of various layers to oxygen, by forming a detexturing layer, by adding oxygen during the ferromagnetic or coupling layer fabrication, and/or by using amorphous materials.

### TECHNICAL FIELD

The present invention generally relates to magnetoelectronic devices such as toggle magnetoresistive random access memory (MRAM) structures, and more particularly relates to exchange-coupled magnetic multilayer structures used in such MRAM devices.

### BACKGROUND

Magnetoresistive random access memory (MRAM) technology combines magnetoresistive components with standard silicon-based microelectronics to achieve non-volatility, high-speed operation, and excellent read/write endurance. In a standard MRAM device, information is stored in the magnetization directions of free magnetic layer in individual magnetic tunnel junctions (MTJ). Referring to FIG. 1, an MTJ 100 generally includes a tunneling barrier 108 between two ferromagnetic layers: free ferromagnetic layer 106, and fixed ferromagnetic layer 110. Each layer 106 and 110 may comprise multiple ferromagnetic layers (a synthetic antiferromagnet, or “SAF”) or a single layer. The fixed layer is typically formed over a pinning layer 120. The structure is typically formed over a seed layer 112 and includes a cap layer 130 over the free layer, and is positioned between two electrodes 102 and 114.

In a standard MRAM, the bit state is programmed to a “1” or “0” using applied magnetic fields generated by currents flowing along two programming lines. The applied magnetic fields selectively switch the magnetic moment direction of free layer 106 for the bit at the intersection of two programming lines as needed to program the bit state. When the magnetic moment directions of free layer 106 and fixed layer 110 are aligned in the same direction, and a voltage is applied across MTJ 100, a lower resistance is measured than when the magnetic moment directions of layers 106 and 110 are set in opposite directions.

For toggle MRAM devices, free layer 106 may consist of a standard SAF as shown in FIG. 2, wherein two ferromagnetic layers 202 and 206 are antiferromagnetically coupled via a coupling layer 204. Magnetization directions are shown by the arrows in layers 202 and 206. Tunneling barrier 108 may comprise a variety of dielectric materials and may have any suitable structure. In one embodiment, for example, tunneling barrier layer 108 comprises an aluminum oxide (AlOₓ layer) having a thickness of about 6-15 Å.

The switching field (H_{sw}) necessary for a toggle transition in a toggle MRAM is related to the magnetic properties of the patterned SAF free layer according to the relationship H_{sw}=\sqrt{HₖHₛₐₜ}, where Hₖ is the anisotropy field of the two ferromagnetic layers in the SAF and Hₛₐₜ is the saturation magnetic field of the SAF, and the point of indeterminate switching. More specifically, Hₖ is the total anisotropy of the ferromagnetic layers in the SAF, which includes contributions from the intrinsic material anisotropy Hₖᵢ, and from shape anisotropy Hₖₛ, so that Hₖ=Hₖᵢ+Hₖₛ. For reliable toggle switching, the vector sum of the applied field pulses should be at least H_{sw} and less than Hₛₐₜ. The difference between Hₛₐₜ and H_{sw} is defined as the operating window and is preferably large enough to prevent errors. Lower H_{sw} is desirable for realizing low power devices. One way to reduce H_{sw} is by reducing Hₛₐₜ as H_{sw}=\sqrt{HₖHₛₐₜ}. However, this approach shrinks the operating window because H_{sw} α√Hₛₐₜ, especially for high Hₖ materials. Also, SAFs are known to be temperature dependant. That is, their magnetic properties are strongly dependent upon the ambient thermal environment, which limits the range of temperatures at which the device may operate. For example, the saturation field, Hₛₐₜ, of a NiFe SAF measured at temperature typically drops, as temperature is increased, at a rate of about 0.4%/° C. (defined as temperature-coefficient (TC)). This drop, though reversible, leads to a reduced operating window at elevated temperature as the Hₛₐₜ drops faster than H_{sw} (since H_{sw} α√Hₛₐₜ).

Free-layer ferromagnetic materials that give rise to high magnetoresistance (MR) due to their large spin polarization, such as NiFeCo and CoFeB, generally have high intrinsic Hₖᵢ. Hereinafter, the term “anisotropy field” refers to the intrinsic anisotropy Hₖᵢ. However, for standard toggle MRAM free layers, such ferromagnetic materials with high Hₖᵢ lead to high switching field and a small operating window for the same Hₛₐₜ.

Many conventional SAF structures used in toggle MRAMs do not have a wide enough operating window for operation in large operating temperature ranges, such as those present in automotive applications. This has prompted the use of multilayer SAFs (e.g., four-layer SAFs), wherein the Hₛₐₜ and H_{sw} can be controlled independently. However, even such multilayer structures, as found by the inventors, are known to exhibit significant temperature dependence.

The multilayer SAF structure is one example of an exchange-coupled magnetic multilayer structure. In the multilayer SAF structure, the thickness of the coupling layers is adjusted to provide antiferromagnetic coupling between the adjacent ferromagnetic layers. For some magnetic devices, including some MRAM free layer structures, it is desirable to have the thickness of one or more of the coupling layers adjusted to provide ferromagnetic coupling.

It is therefore desirable to provide improved exchange-coupled magnetic multilayer structures for MRAM devices that exhibit low power while offering a wide operating temperature range. Other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and

FIG. 1 is a conceptual cross-sectional view of a prior art standard toggle MRAM MTJ;

FIG. 2 is a cross-sectional view of a prior art SAF;

FIG. 3 is a conceptual cross-sectional view of a SAF in accordance with one embodiment.

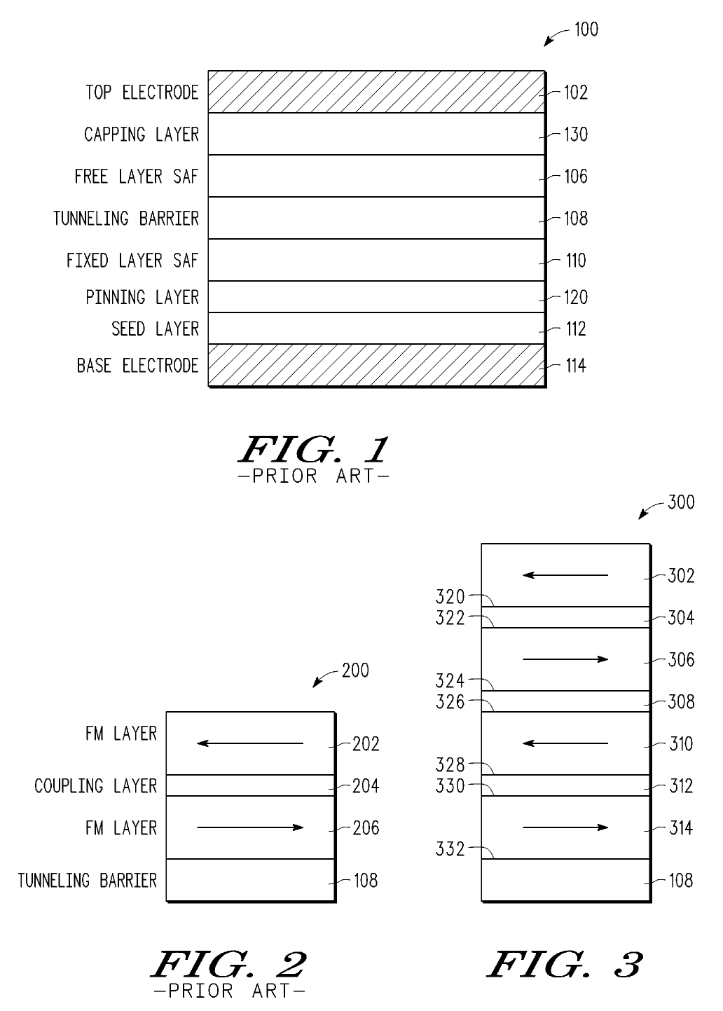

### DETAILED DESCRIPTION

In general, what is described herein are methods and apparatus for a magnetic tunnel junction (MTJ) comprising a synthetic antiferromagnet (SAF) structure formed on a tunnel barrier layer, wherein the SAF includes a plurality (e.g., four or more) ferromagnetic (FM) layers antiferromagnetically or ferromagnetically coupled through a plurality of respective coupling (or “spacer”) layers comprising, for example, Ru. The ferromagnetic layers or the coupling layers are treated to reduce their microcrystalline texture, thereby improving the operating window and temperature range of the SAF. A measure of the amount of microcrystalline texture can be obtained from rocking curves made by varying the sample angle while holding the detector angle fixed on a peak identified in a θ-2θ x-ray diffraction spectrum. Microcrystalline texture is characterized by the full-width-at-half-maximum (FWHM) of the peak obtained from the x-ray rocking curve measurement, which represents the angular distribution of the crystallite orientations present in the material. In one embodiment, the FM layers exhibit a microcrystalline texture characterized by a rocking curve FWHM of greater than approximately 15°.

The following detailed description is merely exemplary in nature and is not intended to limit the range of possible embodiments and applications. Furthermore, there is no intention to be bound by any theory presented in the preceding background or the following detailed description.

For simplicity and clarity of illustration, the drawing figures depict the general structure and/or manner of construction of the various embodiments. Descriptions and details of well-known features and techniques may be omitted to avoid unnecessarily obscuring other features. Elements in the drawing figures are not necessarily drawn to scale: the dimensions of some features may be exaggerated relative to other elements to assist improve understanding of the example embodiments.

Terms of enumeration such as “first,” “second,” “third,” and the like may be used for distinguishing between similar elements and not necessarily for describing a particular spatial or chronological order. These terms, so used, are interchangeable under appropriate circumstances. The embodiments of the invention described herein are, for example, capable of use in sequences other than those illustrated or otherwise described herein. Unless expressly stated otherwise, “connected” means that one element/node/feature is directly joined to (or directly communicates with) another element/node/feature, and not necessarily mechanically. Likewise, unless expressly stated otherwise, “coupled” means that one element/node/feature is directly or indirectly joined to (or directly or indirectly communicates with) another element/node/feature, and not necessarily mechanically.

The terms “comprise,” “include,” “have” and any variations thereof are used synonymously to denote non-exclusive inclusion. The terms “left,” right,” “in,” “out,” “front,” “back,” “up,” “down,” and other such directional terms are used to describe relative positions, not necessarily absolute positions in space. The term “exemplary” is used in the sense of “example,” rather than “ideal.”

In the interest of conciseness, conventional techniques, structures, and principles known by those skilled in the art may not be described herein, including, for example, standard MRAM processing techniques, fundamental principles of magnetism, and basic operational principles of memory devices. For the purposes of clarity, some commonly-used layers may not be illustrated in the drawings, including various protective cap layers, seed layers, and the underlying substrate (which may be a conventional semiconductor substrate or any other suitable structure).

MTJs in accordance with various embodiments may include any number of ferromagnetic layers, and may be incorporated into a variety of structures, such as toggle MRAM, hard disk drive and magnetic sensors and the like. FIG. 3 depicts a SAF structure 300 formed on a tunnel barrier layer 108 in accordance with one embodiment. SAF 300 in this embodiment includes four ferromagnetic layers (i.e., four ferromagnetic layers 302, 306, 310, and 314) separated and antiferromagnetically coupled to each other via respective coupling layers 304, 308, and 312, wherein the bottommost ferromagnetic layer 314 is formed adjacent to tunneling barrier (or “tunnel barrier”) 108. The magnitudes of the antiferromagnetic coupling for each pair can be adjusted by adjusting the layers 304, 308 and 312. In some cases it is desirable to adjust some layers to provide ferromagnetic coupling, for example, 304 and 312 can be adjusted for ferromagnetic coupling while the others are adjusted for antiferromagnetic coupling.

While the entire structure of FIG. 3 may be referred to as a SAF, it will be appreciated that the illustrated structure may be characterized as including multiple SAFs—i.e., one SAF comprising layers 310, 312, and 314, and another SAF comprising layers 302, 304, and 306. These two SAFs, often referred to as the outer SAFs, are antiferromagnetically/ferromagnetically coupled to each other via middle coupling layer 308. The SAF comprising layers 306, 308, and 310 is referred to as the center SAF. Thus, structure 300 is alternatively referred to as a multilayer-SAF, or “ML-SAF.”

In accordance with various embodiments, the MLs and/or coupling layers within structure 300 exhibit a reduced or substantially zero microcrystalline texture (e.g., an x-ray rocking curve FWHM measurement of greater than 10° and preferably greater than 15°), which may also be referred to as a “weak” texture. That is, as it will be understood that the stack shown in FIG. 3 is deposited in a series of layers, starting at 108, and ending with 302, various surfaces are exposed prior to subsequent processing (e.g., surfaces 332, 330, 328, 326, 324, 322, and 320). These surfaces may be subjected to various processing steps to reduce microcrystalline texture of subsequently-formed layers.

The present inventors have found that the increased TCs of Hₛₐₜ and H_{sw} in multilayer SAFs such as those shown in FIG. 3 is due in part to the increase microcrystalline texture of the upper FM layers (e.g., layers 302 and 306). The first FM layer (314) deposited on the amorphous tunnel barrier (e.g., Aluminum Oxide) is quite disordered; however, the microcrystalline texture becomes more pronounced in the later grown FM layers (310, 306 and 302). The increased texture in these upper layers is primarily due to Ru, the coupling layer (312, 308 and 304), which the inventors have found to promote texture in FM layers. In a 4-layer ML SAF as shown, reducing the texture of layers 302 and 306 results in a substantial improvement in TC.

The texture of the various layers may be reduced in a variety of ways. In one embodiment, the texture of the crystalline-based ML SAF layers is reduced by surface treatment (after deposition of the layer, or intermittently)—for example, oxygen exposure (oxygen treatment) for a short duration (5-20 seconds) to the spacer layers (304, 308, 312), after deposition and/or leaking a small amount of O₂ or N₂ during fabrication of FM layers (302, 306, 310, 314) or coupling layers (304, 308, 312). In one embodiment, for example, a NiFe-based ML SAF, wherein the second and third spacers 308 and 304 comprise Ru, are exposed to oxygen for a short duration, typically around 10 seconds. The Ru spacer may be surface treated or doped—for example, with oxygen or nitrogen.

The use of amorphous layers for layers 302, 306, 310, and 314 may also be used to further reduce the texture of these layers. In one embodiment, for example, CoFeB is used for one or more of these layers, where B content is more than 9 atomic percent.

In yet another embodiment, thin layers that are known to reduce the texture of layers grown above them (i.e., “detexturing layers”) can be used—e.g., Aluminum. The inventors have found that Ru (the preferred antiferromagnetic coupling layer) promotes texturing of the ferromagnetic layers grown above it. Growing a thin layer of Al, for example, in the middle of the layer 306 disrupts the texture propagation through the stack.

While FIG. 3 depicts a SAF 300 with four ferromagnetic layers, the range of embodiments is not so limited. Any number of layers may be formed in a particular embodiment. That is, in general, SAF 300 may have N FM layers and N-1 spacer layers, where N-2 FM layers exhibit reduced or substantially zero crystalline texture. In one embodiment, for example, the topmost N-2 FM layers are thus detextured.

As mentioned before, ML SAF structures are proposed as a solution to the operating window issues exhibit significant temperature dependence. In fact, the inventors have found that these ML structures have even less desirable temperature dependence than the conventional toggle MRAM structures. For example, NiFe-based ML structures exhibit a more significant operating temperature dependence of their saturation field, Hₛₐₜ(T) (0.46%/° C. vs. 0.4%/° C.) as well as switching field, H_{sw}(T) (0.46%/° C. vs. 0.32%/° C.) compared to conventional NiFe-based toggle MRAM free layer. As the saturation field is high (which is controlled by the inner SAF), a high Hₛₐₜ(T) is not a major issue; however, higher H_{sw}(T) (controlled by the outer SAFs) can be a significant problem. To address the High H_{sw}(T), it is necessary to raise the temperature compensation, also known as temperature coefficient (TC), built into the circuit to compensate for the change in H_{sw} with temperature. This is undesirable as it leads to a large change in H_{sw} or switching current over the desired operating temperature range.

In addition to the reduced texturing approach, another embodiment designed to improve the poor operating temperature behavior of ML SAFs is a ML SAF wherein the Hₛₐₜ of the outer SAF having a higher TC is maintained at a value greater than the Hₛₐₜ of the outer SAF with a lower TC over the desired temperature range. The outer SAF with the lowest Hₛₐₜ then determines the TC of the switching field for the entire structure; in other words, if the Hₛₐₜ of the outer SAF with lower TC can be maintained lower than the other outer SAFs (having a higher TC) over the desired temperature range, then the entire ML structure will exhibit a better TC of H_{sw}. The preferred structure is a NiFe ML SAF, wherein the process starts with a high Hₛₐₜ for the outer SAF with higher TC (which is the top SAF in the illustrated embodiment). However, the Hₛₐₜ is not so high that Hₛₐₜ differences cause the two outer SAFs to switch independently (i.e., if the two outer SAFs become independent, then the advantage of ML SAF configuration is lost). Such a structure improves the at-temperature behavior of the preferred ML SAF.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the embodiments in any way. Rather, the foregoing detailed description will provide those skilled in the art with a convenient road map for implementing an exemplary embodiment, it being understood that various changes may be made in the function and arrangement of elements described in an exemplary embodiment without departing from the scope as set forth in the appended claims.

1. A method for forming an exchange-coupled magnetic multilayer structure, comprising:
providing a first ferromagnetic layer;
forming a first coupling layer on the first ferromagnetic layer;
forming a second ferromagnetic layer on the first coupling layer;
forming a second coupling layer on the second ferromagnetic layer;
forming a third ferromagnetic layer on the second coupling layer;
forming a third coupling layer on the third ferromagnetic layer; and
forming a fourth ferromagnetic layer on the third coupling layer;
wherein at least one of the second, third and fourth ferromagnetic layers has a substantially zero microcrystalline texture prior to the subsequent forming step.

2. The method of claim 1, wherein the substantially zero microcrystalline texture is characterized by a rocking curve full-width-at-half-maximum (FWHM) greater than approximately 10°.

3. The method of claim 1, wherein the substantially zero microcrystalline texture is produced by oxygen treatment of at least one of the coupling layer.

4. The method of claim 1, wherein the substantially zero microcrystalline texture is produced by forming a detexturing layer that reduces the texture of subsequent layers.

5. The method of claim 4, wherein the detexturing layer comprises Al.

6. The method of claim 1, wherein at least one of the first, second, third and fourth ferromagnetic layers are amorphous layers.

7. The method of claim 1, wherein forming the first coupling layer includes forming a layer of Ru.

8. The method of claim 1, including forming a total of N ferromagnetic layers such that N-2 of the ferromagnetic layers have a substantially zero microcrystalline texture.

9. The method of claim 8, wherein each of the N-2 ferromagnetic layers are formed to have substantially zero microcrystalline texture due to: the addition of at least one detexturing layer, the use of an amorphous layer, the exposure of the coupling layer to oxygen, or addition of oxygen during ferromagnetic or coupling layer fabrications.

10. A an exchange-coupled magnetic multilayer structure comprising:
a plurality of ferromagnetic layers antiferromagnetically or ferromagnetically coupled by a plurality of respective coupling layers, wherein the plurality of ferromagnetic layers includes a first ferromagnetic layer, a second ferromagnetic layer, a third ferromagnetic layer and a fourth ferromagnetic layer, wherein at least one of the second, third, and fourth ferromagnetic layers has a substantially zero microcrystalline texture.

11. The structure of claim 10, wherein the substantially zero microcrystalline texture is characterized by a rocking curve full-width-at-half-maximum (FWHM) greater than approximately 10°.

12. The structure of claim 10, wherein the substantially zero microcrystalline texture is produced by oxygen treatment of at least one of the coupling layers.

13. The structure of claim 10, wherein the substantially zero microcrystalline texture is produced by forming a detexturing layer that reduces the texture of subsequent layers.

14. The structure of claim 13, wherein the detexturing layer comprises Al.

15. The structure of claim 10, wherein at least one of the first, second, third and fourth ferromagnetic layers are amorphous layers.

16. The structure of claim 10, wherein the first coupling layer comprises a layer of Ru.

17. The structure of claim 10, wherein the plurality of ferromagnetic layers includes N ferromagnetic layers, and wherein N-2 of the ferromagnetic layers have a substantially zero microcrystalline texture.

18. The structure of claim 10, wherein each of the N-2 ferromagnetic layers have a substantially zero microcrystalline texture as the result of: the addition of at least one detexturing layer, the use of an amorphous layer, the exposure of the coupling layer to oxygen, or addition of oxygen during the ferromagnetic or coupling layers fabrication.

19. A toggle MRAM device comprising:
a first electrode;
a fixed layer synthetic antiferromagnet (SAF) formed on the first electrode;
a tunneling barrier formed on the fixed layer SAF;
a free layer exchange-coupled magnetic multilayer structure formed adjacent the tunnel barrier layer, wherein the exchange-coupled magnetic multilayer structure comprises a plurality of ferromagnetic layers antiferromagnetically or ferromagnetically coupled by a plurality of respective coupling layers, wherein the plurality of ferromagnetic layers includes a first ferromagnetic layer adjacent the tunnel barrier layer, a second ferromagnetic layer, a third ferromagnetic layer and a fourth ferromagnetic layer, wherein at least one of the first, second, third and fourth ferromagnetic layers has a substantially zero microcrystalline texture;
a cap layer formed on the free layer SAF; and
a second electrode formed on the cap layer.

20. The toggle MRAM of claim 19, wherein the plurality of ferromagnetic layers includes N ferromagnetic layers, and wherein N-2 of the ferromagnetic layers has a substantially zero microcrystalline texture.
